(19) United States
(12) Patent Application Publication
(10) Pub. No.: US 2008/0192014 A1
(43) Pub. Date: Aug. 14, 2008

(54) Touch screen using carbon nanotube electrodes

(75) Inventors: Joel C. Kent, Fremont, CA (US); Daniel H. Scharff, San Leandro, CA (US)

Correspondence Address: Marguerite E. Gerstner;Tyco Electronics Corporation, 307 Constitution Drive, M/S R20/2B, Menlo Park, CA, 94025-1164, US

(73) Assignee: Tyco Electronics Corporation

(21) Appl. No.: 11/704,528

(22) Filed: Feb. 8, 2007

(51) Int. Cl. G06F 3/041

(52) U.S. Cl. 345/173; 977/742

(57) ABSTRACT

A touch screen substrate assembly includes a substrate having a surface at least partially coated with an electrically conductive material to provide an electrically conductive touch area on the surface. At least one electrode is disposed over the substrate adjacent the touch area. The electrode is positioned over the substrate to extend continuously along at least a portion of a perimeter portion of the touch area. The electrode includes carbon nanotubes.

### BACKGROUND OF THE INVENTION

The invention relates generally to computer touch screens, and more particularly, to touch screens having a resistance framing design.

Since their introduction in the early 1970s, touch screens have afforded alternatives to keyboards for certain computer applications. In many situations the keyboard and mouse are eliminated, because the touch screen provides the user with access to the computer. Both resistive and capacitive touch screens typically include a substrate, such as a glass panel, that includes an electrically conductive coating, such as indium tin oxide (ITO), on a surface thereof. The electrically conductive coating defines an electrically conductive area on the substrate surface for accepting a user's inputs to the touch screen. An insulating layer is positioned over the electrically conductive area to provide a surface for the user to touch to select the inputs. For example, in a resistive touch screen, the insulating layer forms a portion of a cover sheet that includes another electrically conductive coating that contacts the electrically conductive coating on the substrate when the cover sheet is touched. In capacitive touch screens, for example, the insulating layer is deposited directly on the electrically conductive coating on the substrate. In operation, a processor electrically connected to the electrically conductive area alternates a voltage on the electrically conductive area. When the insulating layer or cover sheet is touched within the electrically conductive area, an electrical circuit connected to the processor digitizes and transmits the voltages, or equipotentials, or currents of the electrically conductive area to the processor or another processor of a computer with which the touch screen is being used for processing the user's input.

Some known touch screens have a resistance framing design, which includes one or more boundary electrodes disposed on, or under, the electrically conductive coating. The electrode(s) is positioned such that the electrode(s) extends continuously along a perimeter portion of the electrically conductive area, e.g., such that the electrode(s) frames the electrically conductive area. The boundary electrode(s) is electrically connected to the coating of the electrically conductive area to provide an electrical connection between the electrically conductive area and power and ground sources under the control of the touch screen's processor(s).

At least some known conventional boundary electrodes are fabricated from conductive composite polymers, such as polymer inks that include conductive particles of silver or carbon. However, environmental conditions to which touch screens may be subjected during storage and/or use may cause the electrical properties of conventional boundary electrodes to change from the original resistance at the time of manufacture. For example, some temperatures and/or humidities may cause a resistance of conventional boundary electrodes to change from the original manufactured resistance. A change in the electrical properties of the boundary electrode(s) may cause the touch screen to malfunction and/or fail, and at the least may cause the touch screen to function differently than intended. Moreover, some environmental conditions to which touch screens may be subjected during manufacture, storage, and/or use may cause conventional boundary electrodes to fracture, fatigue, and/or separate from the electrically conductive coating. Fracture, failure, and/or separation of the boundary electrode(s) may cause the electrical connection between the electrode(s) and the electrically conductive area to be interrupted. Such interruption may cause the touch screen to malfunction, fail, and/or function differently than intended.

Inorganic materials of solid construction (e.g., tinned copper traces or sintered silver frit) may stand up generally well to environmental conditions, but are too conductive for use as boundary electrodes.

There is a need for a touch screen with an improved boundary electrode that has desired electrical properties and is less sensitive to environmental conditions, such as temperature and/or humidity. There is also a need for a touch screen with a boundary electrode that can survive higher temperatures and/or humidities than conventional boundary electrodes without fracturing, failing, and/or separating from the electrically conductive coating on the touch screen substrate.

### BRIEF DESCRIPTION OF THE INVENTION

In one aspect, a touch screen substrate assembly is provided that includes a substrate having a surface at least partially coated with an electrically conductive material to provide an electrically conductive touch area on the surface. At least one electrode is disposed over the substrate adjacent the touch area. The electrode is positioned over the substrate to extend continuously along at least a portion of a perimeter portion of the touch area. The electrode includes carbon nanotubes.

In another aspect, a touch screen system is provided that includes a substrate having a surface at least partially coated with an electrically conductive material to provide an electrically conductive touch area on the surface. At least one electrode is disposed over the substrate adjacent the touch area. The electrode is positioned over the substrate to extend continuously along at least a portion of a perimeter portion of the touch area. The electrode includes carbon nanotubes. An insulating layer is positioned over at least a portion of the touch area.

### BRIEF DESCRIPTION OF THE DRAWINGS

FIG. 1 is a top plan view of a touch screen substrate assembly formed in accordance with an embodiment of the present invention.

FIG. 2 is a cross-sectional view of the touch screen substrate assembly taken along line 2-2 of FIG. 1.

FIG. 3 is a top plan view of an alternative touch screen substrate assembly formed in accordance with an embodiment of the present invention.

FIG. 4 is a cross-sectional view of the touch screen substrate assembly taken along line 4-4 of FIG. 3.

FIG. 5 is a cross-sectional view of a resistive touch screen system.

FIG. 6 is a cross-sectional view of a capacitive touch screen system.

### DETAILED DESCRIPTION OF THE INVENTION

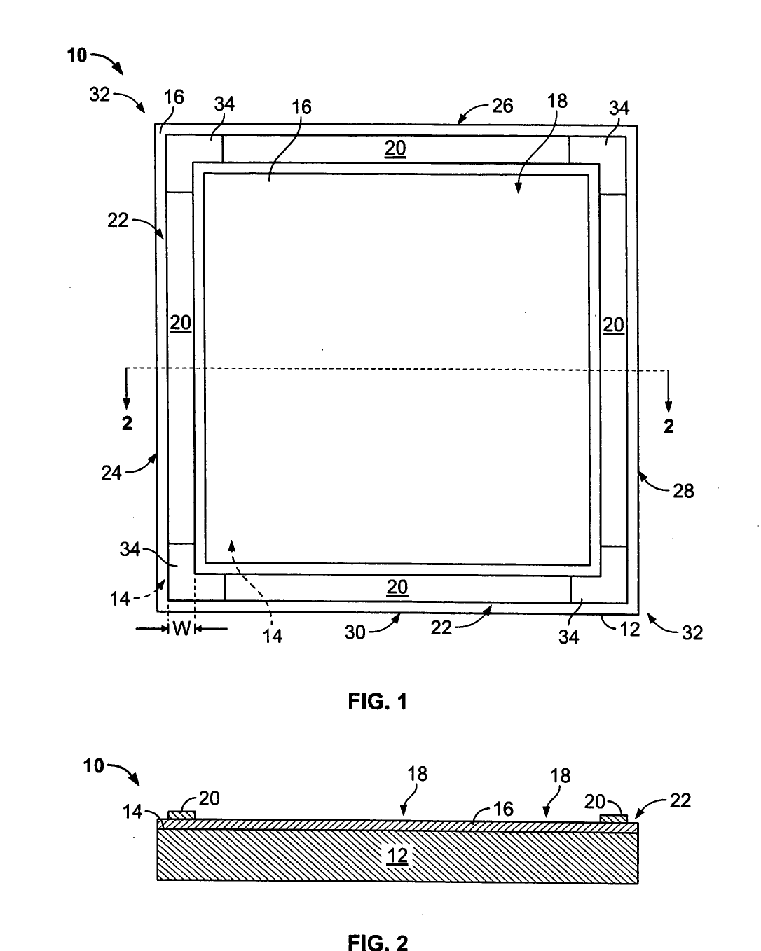

FIG. 1 is a top plan view of a touch screen substrate assembly 10 formed in accordance with an embodiment of the present invention. FIG. 2 is a cross-sectional view of the assembly 10 taken along line 2-2 of FIG. 1. The assembly 10 may be used with any suitable touch screen system, such as, resistive or capacitive systems. Exemplary touch screen systems incorporating the assembly 10 will be described in more detail below. The assembly 10 includes a substrate 12 having a surface 14 at least partially coated with an electrically conductive material 16. The electrically conductive material 16 coating the surface 14 provides an electrically conductive touch area 18 on the surface 14. One or more electrodes 20 frame at least a portion of the touch area 18. The electrodes 20 are formed at least partially from a structure including carbon nanotube, in which carbon nanotubes are the conducting elements.

The substrate 12 may be fabricated from any suitable material(s), that enables the substrate 12 to function as described herein, such as, but not limited to, glass, ceramic, and/or plastic. Depending, for example, on the particular application(s) of the assembly 10 and/or the type of touch screen system(s) the assembly 10 is used with, the substrate 12 and/or the electrically conductive material 16 may be completely transparent, partially transparent, or opaque. The electrically conductive material 16 may include any suitable type(s) of electrically conductive material(s) that enables the electrically conductive material 16 to function as described herein, such as, but not limited to, indium tin oxide (ITO), tin antimony oxide (TAO), graphite containing coatings, and/or metal films.

The electrically conductive material 16 may be coated on the substrate surface 14 in any suitable thickness that enables the electrically conductive material 16 to function as described herein. Generally, the electrically conductive material 16 is coated on the substrate surface 14 at a uniform thickness about the entirety of the touch area 18 to provide consistent electrical properties, such as, but not limited to resistance, about the entirety of the touch area 18. The material(s) and/or thickness, for example, of the electrically conductive material 16 may be selected to provide any suitable resistance that enables the electrically conductive material 16 to function as described herein, such as, but not limited to, a resistance of between about 100 Ohms/square and about 1000 Ohms/square. The selected resistance may depend, for example, on the particular application(s) of the assembly 10 and/or the type of touch screen system(s) the assembly 10 is used with. The coating of the electrically conductive material 16 may be applied to the substrate surface 14 using any suitable structure, method, process, and/or means that enables the electrically conductive material to function as described herein, such as, but not limited to, sputtering, dipping, spraying, chemical vapor deposition, spinning, and/or screen printing operations. The touch area 18 may have any suitable size and/or shape, such as, but not limited to rectangular, circular, triangular, and/or oval-shaped, that enables the touch area 18 to function as described herein, for example, depending on the particular application(s) of the assembly 10 and/or the type of touch screen system(s) the assembly 10 is used with. In the exemplary embodiments, the touch area 18 has a generally rectangular shape and covers the area of the substrate surface 14 that is framed by the electrodes 20.

As discussed briefly above, one or more electrodes 20 frames at least a portion of the touch area 18. Specifically, the electrodes 20 are disposed over the substrate surface 14. In the exemplary embodiments, the assembly 10 includes four separate electrodes 20 each disposed directly on the electrically conductive material 16 at a different location about a perimeter portion 22 of the touch area 18. The touch area 18 is bordered by sides 24, 26, 28, 30 that form the perimeter portion 22, with corner portions 32. Each of the electrodes 20 extends along a corresponding different side 24, 26, 28, 30 of the rectangular-shaped touch area 18. In the exemplary embodiment, the four electrodes 20 are electrically connected to each adjacent electrode 20 at the corresponding corner portion 32 of the touch area 18. The electrodes 20 are electrically connected, in the exemplary embodiment, using an electrically conductive material 34 disposed on the electrically conductive material 16 adjacent the corner portions 32. The electrically conductive material 34 may include any suitable material(s) that enables the electrically conductive material 34 to function as described herein, such as, but not limited to, silver frit, copper, and/or the same or similar material(s) as the electrodes 20.

As the electrodes 20 are positioned on each side 24, 26, 28, 30 of the touch area 18 and are interconnected at the corner portions 32, the electrodes 20 extend continuously along an entirety of the perimeter portion 22 of the touch area 18 and therefore completely frame the touch area 18. Alternatively, the electrodes 20 may be positioned on the electrically conductive material 16 such that the electrodes 20 extend along only a portion of the perimeter portion of the touch area 18 (e.g., along only two sides of the exemplary rectangular touch area 18). Moreover, rather than being connected using the electrically conductive material 34, two or more of the electrodes 20 may be directly connected together. For example, the electrodes 20 extending along two or more sides (e.g., the sides 24, 26) may be directly connected together. In some embodiments, for example, one continuous electrode 20 extends continuously along an entirety of the perimeter portion 22 of the touch area 18 and therefore completely frames the touch area 18. Separate electrodes 20 may be connected together at other locations than the corner portions 32 in other embodiments not shown herein. In the exemplary embodiments, the electrodes 20 are configured to be electrically connected at the corner portions 32 to any processor(s) (not shown) and/or power and ground sources (not shown) related to a touch screen system with which the assembly 10 is used.

Although the electrodes 20 are disposed directly on the electrically conductive material 16 in the exemplary embodiments of FIGS. 1, 2, 5, and 6, the electrodes 20 may alternatively be disposed directly on the substrate surface 14 between the substrate surface 14 and the electrically conductive material 16.

The electrodes 20 are constructed at least partially from carbon nanotubes. The electrodes 20 may have any suitable structure including carbon nanotubes that enables the electrodes 20 to function as described herein. For example, the carbon nanotubes may be pristine, functionalized, and/or filled with another material, such as, but not limited to, a metal, to form “nanowires” encapsulated within carbon nanotube lumens. Examples of structures including carbon nanotubes that may be suitable for constructing the electrodes 20 include layers, films, and/or non-woven fabrics of entangled and/or matted carbon nanotubes (hereinafter referred to as “carbon nanotube fabric”). Directed growth and/or chemical self-assembly of individual carbon nanotubes may be used to grow or deposit the individual nanotubes with suitably controlled orientation, length, and the like. Thus, the electrodes 20 may be constructed from individual carbon nanotubes that are directly grown and/or chemically self-assembled. Generally, constructing the electrodes 20 from a carbon nanotube structure retains many if not all of the benefits of individual nanotubes. Moreover, carbon nanotube structures may have benefits not found in individual nanotubes. For example, because the carbon nanotube structure is composed of a plurality of carbon nanotubes in aggregation, the electrode 20 will not fail as a result of a failure and/or break of an individual carbon nanotube. Rather, there are a plurality of alternate paths through which electrons may travel within the electrode 20. In effect, an electrode 20 constructed from a carbon nanotube structure creates its own electrical network of individual carbon nanotubes within the electrode 20, each of which may conduct electrons. The carbon nanotube structure may include single-walled carbon nanotubes and/or multi-walled carbon nanotubes. Each electrode 20 may be constructed of a carbon nanotube structure that is a monolayer of carbon nanotubes, or may optionally be constructed from a carbon nanotube structure that includes a plurality of layers of carbon nanotubes.

The carbon nanotube fabric and/or other type of carbon nanotube construction(s) used to fabricate the electrodes 20 may be grown directly on the electrically conductive material 16 on the substrate 12 (e.g., using a mask or etching processes to form the electrodes 20), or may be pre-grown and deposited on the material 16 on the substrate 12. The carbon nanotube fabric and/or other type of carbon nanotube construction(s) used to fabricate the electrodes 20 may be applied on the electrically conductive area 16 of the substrate 12 using any suitable method, process, structure, and/or means that enables the electrodes 20 to function as described herein, such as, but not limited to, spin coating, dipping, spraying (e.g., aerosol application), screen printing operations, and/or growth directly on the material 16 (e.g., spin-coated catalyst-based growth and/or gas-phase catalyst-assisted chemical vapor deposition. In some deposition processes, such as, but not limited to, spin coating, spraying, dipping, and/or screen printing processes, the carbon nanotubes may be suspended in a suitable solvent in a soluble or insoluble form. Parameters for controlling such exemplary types of application to the material 16 include surface functionalization of the underlying surface, spin-coating parameters (e.g., length, nanotube/nanotube suspension concentration, spin coating solution concentration, and/or revolutions per minute (RPM), a number of applications, temperature, pH, time, catalyst density/concentration, and/or growth environment (e.g., growth time, growth temperature, and/or gas concentration). The carbon nanotubes may optionally be functionalized (e.g., with planar conjugated hydrocarbons such as, but not limited to, pyrenes) to aid in enhancing the internal adhesion between nanotubes. During some of the applications discussed herein, the carbon nanotubes may exhibit a “self-assembly” trait where individual nanotubes tend to adhere to a surface to which they are applied whenever energetically favorable. Individual carbon nanotubes may adhere to each other as a consequence of attractive van der Waals forces, depending, for example, on the particular application(s) of the assembly 10 and/or the type of touch screen system(s) the assembly 10 is used with. In other embodiments van der Waals interactions between the carbon nanotubes may be repulsive or neutral.

The electrodes 20 may each have any suitable size, for example length, width W, and/or thickness, that enables the electrodes 20 to function as described herein, such as, but not limited to, a width W of between about 0.4 mm and about 3 mm, and/or a thickness less than about 25 microns. The width(s), length(s), thickness(es), material construction, for example, of each electrode 20 may be selected to provide any suitable resistance and/or electrical conductivity that enables the electrodes 20 to function as described herein, such as, but not limited to, a resistivity of between about 0.1 Ohms/square and about 10 Ohms/square. Moreover, and for example, a porosity of the electrodes 20, for example a porosity of a carbon nanotube fabric used to construct the electrodes 20, may be selected to provide the desired resistance and/or electrical conductivity. Other examples of parameters and/or processes that may provide a desired resistance and/or electrical conductivity include heating the carbon nanotube structure used to construct the electrodes and/or exposing the carbon nanotube structure to reactive ions, such as, but not limited to, halogen ions. Such heating and/or exposing to reactive ions may be done before, during, or after the carbon nanotube structure is applied to the substrate 12 to form the electrodes 20. The selected electrical properties (e.g., resistivity(ies) and/or electrical conductivity(ies)) may depend, for example, on the particular application(s) of the assembly 10 and/or the type of touch screen system(s) the assembly 10 is used with. Depending, for example, on the particular application(s) of the assembly 10 and/or the type of touch screen system(s) the assembly 10 is used with, the electrodes 20 may be completely transparent, partially transparent, or opaque.

The carbon nanotube compositions used to fabricate the electrodes 20 provide the electrodes 20 with electrical properties and mechanical properties that are insensitive to environmental conditions, such as, but not limited to, temperature and/or humidity. The electrodes 20 exhibit substantially consistent resistance and reliable electrical connection to the electrically conductive material 16 at the time of manufacture which will not change when the electrodes 20 are subjected to ambient temperatures between about −40° C. and about 85° C., and/or ambient relative humidities between about 0% and about 85%. Moreover, and for example, the electrodes 20 may not fracture, fail, and/or separate from the electrically conductive material 16 (and thus the touch area 18) when the electrodes 20 are subjected to temperatures between about −40° C. and about 85° C. during storage, use, and/or manufacturing of a touch screen system that includes the electrodes 20.

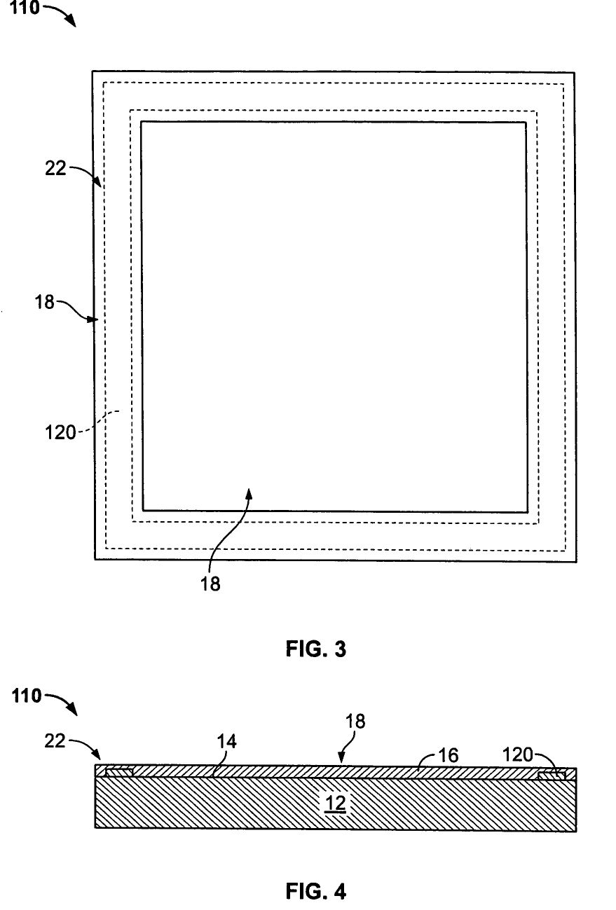

FIGS. 3 and 4 illustrate an alternative embodiment of an electrode assembly 110 substantially similar to the assembly 10 (FIGS. 1 and 2) except that one continuous electrode 120 extends continuously along an entirety of the perimeter portion 22 of the touch area 18 and therefore completely frames the touch area 18. Moreover, in contrast to the embodiments shown in FIGS. 1 and 2, the electrode 120 is disposed directly on the substrate surface 14 between the substrate surface 14 and the electrically conductive material 16.

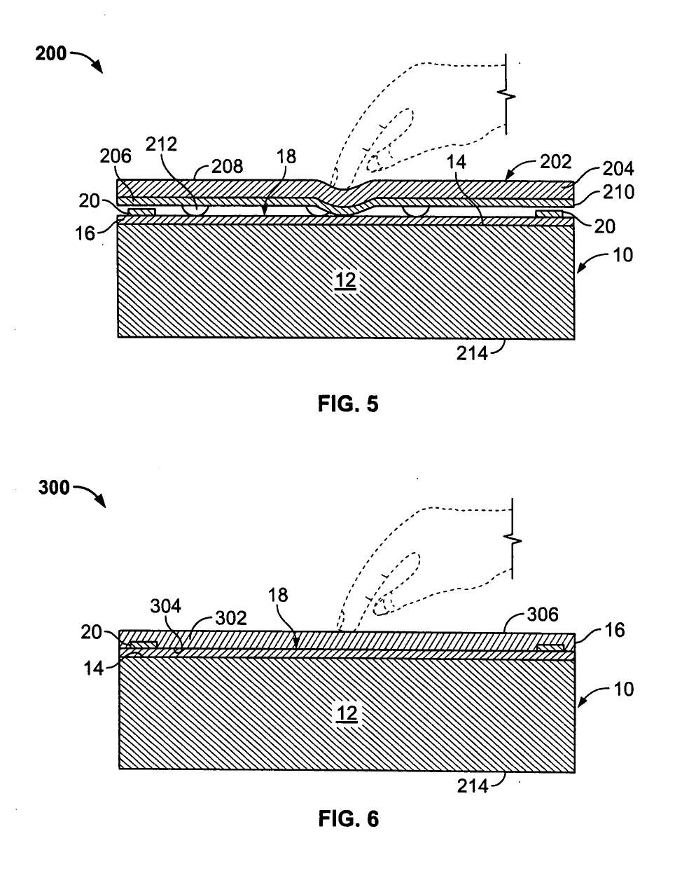

FIG. 5 is a cross-sectional view of a resistive touch screen system 200 that may include the touch screen substrate assembly embodiments described and illustrated herein. The system 200 may be mounted on any suitable display (not shown), such as, but not limited to, LCD, plasma, and/or CRT displays of any suitable computer or other device (not shown). The system 200 includes the assembly 10 (shown in FIGS. 1 and 2), which as discussed above includes the substrate 12, the electrically conductive material 16, and the electrodes 20. The system 200 also includes a cover sheet 202 positioned over the touch area 18 of the assembly 10. The cover sheet 202 includes an insulating layer 204 having opposite surfaces 206, 208. The surface 206 is at least partially coated with an electrically conductive material 210 and the cover sheet 202, including the electrically conductive material 210 is spaced from the substrate 12 by a plurality of insulating dots 212. Specifically, the insulating dots 212 space the electrically conductive material 210 of the cover sheet 202 from the electrically conductive material 16 on the substrate 12. The cover sheet 202 may also include a coating (not shown) on the surface 208 to increase a durability of the cover sheet 202 generally and/or the surface 208 of the insulating layer 204 specifically.

A surface 214 of the substrate 12 opposite the surface 14 is typically placed over a face (not shown) of the display with which the touch screen is being used. In operation, a processor (not shown) electrically connected to the touch area 18 alternates a voltage across the touch area 18 in the X and Y directions. When a user makes an input by touching the cover sheet 202 at a location within the touch area 18, the touch causes the cover sheet 202 to move toward the substrate 12. Movement of the cover sheet 202 towards the substrate causes the electrically conductive material 210 on the cover sheet 202 to engage, and thereby make electrical contact with, the electrically conductive material 16 on the substrate 12 at the location of the movement, or touch. An electrical circuit (not shown) connected to the processor digitizes the voltages or equipotentials caused by the touch and transmits the voltages or equipotentials to the processor, or a processor of the computer or other device, for processing the user's input.

The electrically conductive material 210 may include any suitable type(s) of electrically conductive material(s) that enables the electrically conductive material 16 to function as described herein, such as, but not limited to, indium tin oxide (ITO). The insulating layer 204 of the cover sheet 202 may be fabricated from any suitable material(s) that enables the cover sheet 102 to function as described herein, such as, but not limited to polyester.

FIG. 6 is a cross-sectional view of a capacitive touch screen system 300 that may include the touch screen substrate assembly embodiments described and illustrated herein. The system 300 may be mounted on any suitable display (not shown), such as, but not limited to, LCD, plasma, and/or CRT displays of any suitable computer or other device (not shown). The system 300 includes the assembly 10 (shown in FIGS. 1 and 2), which as discussed above includes the substrate 12, the electrically conductive material 16, and the electrodes 20. The system 300 also includes an insulating layer 302 positioned over the touch area 18 of the assembly 10. Specifically, a surface 304 of the insulating layer 302 facing the substrate 12 is disposed directly on the electrically conductive material 16 on the substrate 12. The insulating layer 302 may also include a coating (not shown) on a surface 306 opposite the surface 304 to increase a durability of the insulating layer 302 generally and/or the surface 306 specifically.

The surface 214 of the substrate 12 opposite the surface 14 is typically placed over a face (not shown) of the display with which the touch screen is being used. In operation, a processor (not shown) electrically connected to the touch area 18 alternates a voltage on the touch area 18. When a user makes an input by touching the insulating layer 302 at a location within the touch area 18, an AC electrical current is drawn from the electrically conductive material 16 and shunted to ground through the user's body. The current to ground through the user is supplied by electrical circuits (not shown) connected to the corner portions 32 (FIG. 1) of the touch area 18 (whether connected to the electrodes 20 or the electrically conductive material 34, shown in FIG. 1). Of the total AC current supplied to the four corner portions 32, the fraction supplied to the right top and right bottom corner portions 32 provides a measure of the X coordinate of the touch and the fraction supplied to the top tow corner portions 32 provides a measure of the Y coordinate of the touch. The electrical circuits provide measurements of the corner currents which are communicated to the processor, or a processor of the computer or other device, for processing the user's input.

The insulating layer 302 may be fabricated from any suitable material(s) that enables the insulating layer 302 to function as described herein, such as, but not limited to, silicon dioxide, alumina and/or other transparent inorganic oxides, diamond, and/or diamond-like carbon coatings.

The embodiments described and/or illustrated herein provide touch screens that may be less likely to malfunction, fail, and/or function differently than intended than known touch screens when exposed to environmental conditions, such as, but not limited to, temperature and/or humidity, during storage, use, and/or manufacturing. The use of the embodiments described and/or illustrated herein may enable greater freedom of choice of temperatures and/or humidities during use as well as during manufacturing of touch screens as compared to known touch screens.

Exemplary embodiments are described and/or illustrated herein in detail. The embodiments are not limited to the specific embodiments described herein, but rather, components and/or steps of each embodiment may be utilized independently and separately from other components and/or steps described herein. Each component, and/or each step of one embodiment, can also be used in combination with other components and/or steps of other embodiments. For example, although specific sensor elements are described and/or illustrated with specific attachment devices, each described and/or illustrated sensor element may be used with any of the described and/or illustrated attachment devices as is appropriate. When introducing elements/components/etc. described and/or illustrated herein, the articles “a”, “an”, “the”, “said”, and “at least one” are intended to mean that there are one or more of the element(s)/component(s)/etc. The terms “comprising”, “including” and “having” are intended to be inclusive and mean that there may be additional element(s)/component(s)/etc. other than the listed element(s)/component(s)/etc. Moreover, the terms “first,” “second,” and “third,” etc. in the claims are used merely as labels, and are not intended to impose numerical requirements on their objects. Further, the limitations of the following claims are not written in means—plus-function format and are not intended to be interpreted based on 35 U.S.C. §112, sixth paragraph, unless and until such claim limitations expressly use the phrase “means for” followed by a statement of function void of further structure.

While the invention has been described in terms of various specific embodiments, those skilled in the art will recognize that the invention can be practiced with modification within the spirit and scope of the claims.

What is claimed is:

1. A touch screen substrate assembly comprising:
a substrate having a surface at least partially coated with an electrically conductive material to provide an electrically conductive touch area on the surface; and
at least one electrode disposed over the substrate adjacent the touch area, the electrode being positioned over the substrate to extend continuously along at least a portion of a perimeter portion of the touch area, and the electrode comprising carbon nanotubes.

2. A touch screen substrate assembly according to claim 1, wherein the electrode extends continuously along an entirety of the perimeter portion of the touch area such that the electrode completely frames the touch area.

3. A touch screen substrate assembly according to claim 1, wherein the touch area comprises a generally rectangular shape, the electrode extending continuously along at least two sides that at least partially define the perimeter portion of the touch area.

4. A touch screen substrate assembly according to claim 1, wherein the electrode is disposed directly on the substrate surface between the substrate surface and the electrically conductive material.

5. A touch screen substrate assembly according to claim 1, wherein the electrode is disposed directly on the electrically conductive material.

6. A touch screen substrate assembly according to claim 1, wherein the electrically conductive material comprises at least one of indium tin oxide (ITO) and tin antimony oxide (TAO).

7. A touch screen substrate assembly according to claim 1, wherein the substrate comprises at least one of glass, plastic, and ceramic.

8. A touch screen substrate assembly according to claim 1, wherein the electrode comprises a resistivity of between about 0.1 Ohms/square and about 10 Ohms/square.

9. A touch screen system comprising:
a substrate having a surface at least partially coated with an electrically conductive material to provide an electrically conductive touch area on the surface;
at least one electrode disposed over the substrate adjacent the touch area, the electrode being positioned over the substrate to extend continuously along at least a portion of a perimeter portion of the touch area, and the electrode comprising carbon nanotubes; and
an insulating layer positioned over at least a portion of the touch area.

10. A touch screen system according to claim 9, wherein the electrode extends continuously along an entirety of the perimeter portion of the touch area such that the electrode completely frames the touch area.

11. A touch screen system according to claim 9, wherein the touch area comprises a generally rectangular shape, the electrode extending continuously along at least two sides that at least partially define the perimeter portion of the touch area.

12. A touch screen system according to claim 9, wherein the electrode is disposed directly on the substrate surface between the substrate surface and the electrically conductive material.

13. A touch screen system according to claim 9, wherein the electrode is disposed directly on the electrically conductive material between the electrically conductive material and the insulating layer.

14. A touch screen system according to claim 9, wherein the electrically conductive material at least partially coating the substrate surface is a first coating of electrically conductive material, the insulating layer forming a portion of a cover sheet that is spaced from the substrate, the cover sheet comprising a second coating of an electrically conductive material on a surface of the insulating layer facing the substrate, the second coating of electrically conductive material on the insulating layer surface being configured to electrically connect to the first coating of electrically conductive material on the substrate surface at locations where a portion of the cover sheet is moved toward the substrate such that the first and second coatings are engaged.

15. A touch screen system according to claim 10, wherein the cover sheet is spaced from the substrate by a plurality of insulating dots.

16. A touch screen system according to claim 9, wherein a surface of the insulating layer facing the substrate is disposed directly on the electrically conductive material on the substrate surface.

17. A touch screen system according to claim 9, wherein the substrate comprises at least one of glass, plastic, and ceramic.

18. A touch screen system according to claim 9, wherein the insulating layer comprises polyester.

19. A touch screen system according to claim 9, wherein the electrode comprises a resistivity of between about 0.1 Ohms/square and about 10 Ohms/square.

20. A touch screen system according to claim 9, wherein the touch screen system is one of a resistive touch screen system and a capacitive touch screen system.
